(19) United States
(12) Patent Application Publication
(10) Pub. No.: US 2025/0063784 A1
(43) Pub. Date: Feb. 20, 2025

(54) PROCESS FOR THE MANUFACTURE OF A SEMICONDUCTOR STRUCTURE COMPRISING A POLYCRYSTALLINE SILICON CARBIDE SUBSTRATE AND AN ACTIVE LAYER OF SINGLE-CRYSTAL SILICON CARBIDE

(71) Applicant: Soitec, BERNIN (FR)

(72) Inventors: Hugo Biard, BERNIN (FR); Eric Guiot, BERNIN (FR)

(21) Appl. No.: 18/718,313

(22) PCT Filed: Dec. 13, 2022
(86) PCT No.: PCT/FR2022/052331

§ 371 Date: Jun. 10, 2024

(30) Foreign Application Priority Data
Dec. 14, 2021 (FR) FR2113508

(51) Int. Cl. H01L 29/16; H01L 21/02

(52) U.S. Cl. CPC H01L 29/1608; H01L 21/02378; H01L 21/02529; H01L 21/0257

(57) ABSTRACT

A method of manufacturing a semiconductor structure, which includes a support substrate of polycrystalline silicon carbide and an active layer of single-crystal silicon carbide, involves:
the formation of a support substrate including a stack of a first layer of polycrystalline SiC mainly of polytype 3C and of a second layer of polycrystalline SiC mainly of polytype 4H and/or 6H,
the bonding of a donor substrate including an active layer of single-crystal SiC of polytype 4H or 6H to a face of polytype 4H and/or 6H of the support substrate, and
the transfer of the active layer onto the support substrate.

### CROSS REFERENCE TO RELATED APPLICATIONS

This application is a national phase entry under 35 U.S.C. § 371 of International Patent Application PCT/FR2022/052331, filed Dec. 13, 2022, designating the United States of America and published as International Patent Publication WO 2023/111446 Al on Jun. 22, 2023, which claims the benefit under Article 8 of the Patent Cooperation Treaty to French Patent Application Serial No. FR2113508, filed Dec. 14, 2021.

### TECHNICAL FIELD

The present disclosure relates to a process for the manufacture of a semiconductor structure comprising a support substrate of polycrystalline silicon carbide and an active layer of single-crystal silicon carbide, and also to such a structure and to an electronic device comprising such a structure, in particular, for power applications or radiofrequency applications.

### BACKGROUND

Silicon carbide (SiC) is an advantageous material in microelectronics, in particular, in the manufacture of substrates for electronic devices intended for power applications.

These microelectronic devices comprise an active layer of single-crystal SiC, in or on which are formed transistors and other electronic components suitable for fulfilling the required functions.

The active layer is arranged on a support substrate of polycrystalline SiC doped in order to exhibit a good electrical conductivity. This is because, in these devices, the electric current applied to the transistors and other electrical components of the active layer passes through the substrate, in the direction of its back face, which is the face opposite the active layer.

The formation of a semiconductor structure comprising the active layer and the support substrate can be carried out by the Smart Cut™ process. According to this process, a weakened zone delimiting the active layer is formed by implantation of atomic entities in a donor substrate of single-crystal SiC, the donor substrate is bonded to a support substrate of polycrystalline SiC, then the donor substrate is detached along the weakened zone so as to transfer the active layer onto the support substrate. The detaching can be initiated by a mechanical action, a heat treatment or any other suitable means, it being possible for the means to be optionally combined.

The SiC exhibits several polytypes, that is to say different crystal structures. The main polytypes used in the field of microelectronics are the polytype 3C, of cubic structure, and the polytypes 4H and 6H, of hexagonal structure. These polytypes differ, in particular, in their unit cell parameter, in their electronic band diagrams and in their thermal expansion coefficient.

In general, polycrystalline SiC substrates are commercially available in the 3C form. This is because this polytype can be obtained by chemical vapor deposition on a seed substrate, generally made of graphite, at a relatively low temperature, that is to say typically of less than or equal to 1400° C., so that the manufacturing process is relatively economical in energy.

On the other hand, single-crystal SiC substrates are commercially available, in dimensions of use in the industry, that is to say typically on the order of 150 to 200 mm in diameter, with a hexagonal structure, of 4H or 6H type.

Consequently, the assembling of an active layer of polycrystalline SiC of 4H type and of a support substrate of polycrystalline SiC involves the formation of an interface exhibiting two types of discontinuities: a discontinuity in terms of crystalline quality (monocrystalline/polycrystalline) and a discontinuity in terms of crystal structure (hexagonal/cubic).

These two discontinuities are capable of causing several problems affecting the performance qualities of the structure.

On the one hand, the difference in thermal expansion coefficient can cause a deformation of the structure when the latter is subjected to a high thermal budget.

Such a thermal budget can be applied to the structure on the occasion of an annealing intended to reinforce the bonding interface. This is because the known processes do not make possible direct bonding of the donor substrate to the support substrate and require the use of a bonding layer, for example, made of doped silicon. The bonding is then frequently followed by a stabilization annealing carried out at a temperature on the order of 1700° C.

A high thermal budget, typically between 1500 and 2000° C., can also be applied during a subsequent phase of manufacture of the electronic device, for example, when an epitaxy is carried out on the active layer in order to form other parts of the electronic device, or during a heat treatment for activation of dopants.

The deformation due to the difference in thermal expansion coefficient can damage the flatness of the structure, which is prejudicial to the implementation of the subsequent stages of manufacture of the electronic device, and reduce the mechanical strength of the bonding.

On the other hand, the difference in crystalline quality, which does not make possible an alignment of the crystalline grains on either side of the bonding interface, can cause a loss of electrical conductivity at the interface.

### BRIEF SUMMARY

One aim of the present disclosure is to design a process for the manufacture of a semiconductor structure comprising an active layer of single-crystal SiC on a support substrate of polycrystalline SiC, which makes it possible to minimize the disadvantages related to the difference in crystalline quality and in polytype at the interface between the active layer and the support substrate.

To this end, the present disclosure provides a process for the manufacture of a semiconductor structure comprising a support substrate of polycrystalline silicon carbide (SiC) and an active layer of single-crystal silicon carbide, comprising:
the formation of a support substrate comprising a stack of a first layer of polycrystalline SiC mainly of polytype 3C and of a second layer of polycrystalline SiC mainly of polytype 4H and/or 6H,
the bonding of a donor substrate comprising an active layer of single-crystal SiC of polytype 4H or 6H to a face of polytype 4H and/or 6H of the support substrate, and
the transfer of the active layer onto the support substrate.

Thus, in the final structure, the interface between the layers of different crystalline qualities (which remains at the bonding interface between the active layer and the support substrate) and the interface between the layers of different polytypes (which is buried in the support substrate, at a distance from the bonding interface) have been split up.

In the present text, the term “mainly of polytype 3C” means that the proportion by volume of grains of 3C structure in the first layer is greater than or equal to 60%, preferably greater than or equal to 70%, indeed even greater than or equal to 80%. Likewise, the expression “mainly of polytype 4H and/or 6H” means that the proportion by volume of grains of 4H and/or 6H structure in the second layer is greater than or equal to 60%, preferably greater than or equal to 70% and more preferably greater than or equal to 80%.

In the present text, the terms “first” and “second” denote the two layers of polycrystalline SiC of different polytypes of the support substrate, without resulting in a particular order of formation of the layers.

Thus, in some embodiments, the first layer is grown on a seed substrate and then the second layer is grown on the first layer, so that the support substrate directly exhibits a free surface mainly of polytype 4H and/or 6H for the bonding of the donor substrate.

In other embodiments, the second layer is grown on a seed substrate and then the first layer is grown on the second layer. In this case, in order to enable the bonding of the donor substrate to a face mainly of polytype 4H and/or 6H of the support substrate, the seed substrate is withdrawn in order to release the face of the second layer located on the side of the seed substrate.

According to other advantageous but optional characteristics, optionally in combination when technically feasible:
the formation of the support substrate comprises the growth of the first layer on a seed substrate and then the growth of the second layer on the first layer;
the formation of the support substrate successively comprises the growth of the second layer on a seed substrate, the growth of the first layer on the second layer and the withdrawal of the seed substrate in order to expose a face of the second layer for the bonding of the donor substrate;
the seed substrate is a single-crystal or polycrystalline SiC substrate mainly of polytype 4H and/or 6H;
the first layer is grown over a thickness of between 1 and 20 μm, and the second layer is grown over a thickness of between 80 and 350 μm;
the first layer is grown over a thickness of between 80 and 200 μm, and the second layer is grown over a thickness of between 150 and 270 μm;
the growth of the first and of the second layer is carried out by chemical vapor deposition (CVD);
the growth of the first layer is carried out at a temperature of between 1100 and 1500° C., preferably between 1200 and 1400° C.;
the growth of the second layer is carried out at a temperature of between 1500 and 2600° C., preferably between 1700 and 1900° C., or between 1800 and 2400°° C., indeed even between 2000 and 2250° C.;
the process additionally comprises the introduction of dopants during the growth of the first and of the second layer;
the donor substrate is bonded directly to the face of polytype 4H and/or 6H of the support substrate;
the donor substrate is bonded to the face of polytype 4H and/or 6H of the support substrate via a bonding layer;
the bonding layer comprises silicon or tungsten;
the process comprises, before the bonding, a stage of implantation of atomic entities in the donor substrate in order to form a weakened zone delimiting the active layer and, after the bonding, a stage of detachment of the donor substrate along the weakened zone in order to transfer the active layer onto the support substrate;
in the case where the first layer is grown over a thickness of between 1 and 20 μm, the first layer is withdrawn after the transfer of the active layer onto the support substrate.

Another aspect of the present disclosure relates to a semiconductor structure successively comprising, from its back face to its front face:
a first layer of polycrystalline SiC mainly of polytype 3C,
a second layer of polycrystalline SiC mainly of polytype 4H and/or 6H, and
an active layer of single-crystal SiC of polytype 4H or 6H.

In the present text, the term “successively” specifies a spatial order of the layers but does not necessarily result in direct contact between the layers.

In some embodiments, the first layer exhibits a thickness of between 80 and 350 μm and the second layer exhibits a thickness of between 1 and 20 μm.

In other embodiments, the first layer exhibits a thickness of between 80 and 200 μm and the second layer exhibits a thickness of between 150 and 270 μm.

Another aspect of the present disclosure relates to an electronic device, in particular, for power applications or radiofrequency applications, comprising a structure as described above and at least one electronic component, such as a transistor, a diode, an electronic power component and/or an electronic radiofrequency component, arranged in or on the active layer.

### BRIEF DESCRIPTION OF THE DRAWINGS

Other characteristics and advantages of the present disclosure will emerge from the detailed description that will follow, with reference to the appended drawings, in which:

FIG. 1 represents a cross-sectional view of a semiconductor structure according to a first embodiment;

FIG. 2 represents a cross-sectional view of a structure according to a second embodiment;

FIGS. 3A to 3D diagrammatically represent stages of a process for the manufacture of the semiconductor structure of FIG. 1;

FIGS. 4A to 4D diagrammatically represent stages of a process for the manufacture of the semiconductor structure of FIG. 2; and

FIGS. 5A to 5D diagrammatically represent stages of an alternative form of the processes of FIGS. 3A-3D and 4A-4D.

For reasons of readability, the drawings are not necessarily produced to scale.

### DETAILED DESCRIPTION

The present description relates to a semiconductor structure comprising a support substrate of polycrystalline SiC and an active layer of single-crystal SiC extending over the support substrate.

The support substrate comprises two layers of polycrystalline SiC of different polytypes: a first layer mainly of polytype 3C and a second layer mainly of polytype 4H and/or 6H.

The first and the second layer of polycrystalline SiC can be provided according to different configurations in the structure, which configurations will be described below.

The active layer is made of single-crystal SiC in order to exhibit optimum electrical properties. The active layer exhibits a hexagonal structure, mainly of polytype 4H or 6H.

The active layer is added by bonding to the support substrate, on a face of polytype 4H and/or 6H. This bonding can be direct or indirect, via a bonding layer.

It should be noted that the active layer is bonded to a layer of polycrystalline SiC of a polytype that is also hexagonal. Thus, the materials present at the bonding interface exhibit structures with closer bands than in the case of a bonding between a material of hexagonal structure and a material of cubic structure, which can be favorable to a better electrical conductivity at the interface. Furthermore, this similarity between the hexagonal structures present at the interface makes it possible to reduce the difference in thermal expansion coefficient on either side of the interface. For this reason, it is possible to avoid the risks of plastic deformation during the high-temperature manufacturing stages, and also the defects of focusing due to curvatures of the structure during the lithography stages carried out subsequently for the manufacture of electronic devices.

Whatever the arrangement of the first and of the second layer of polycrystalline SiC forming the support substrate, two interfaces of different natures are present within the structure.

A first interface is the interface between the single-crystal active layer and the polycrystalline support substrate, which is an interface between layers of different crystalline qualities but of similar polytypes.

A second interface is the interface between the first and the second layer of polycrystalline SiC of the support substrate, which is an interface between layers of different polytypes but of similar crystalline qualities. This second interface is located in the thickness of the support substrate and is thus distant from the first interface.

It should be noted that the second interface does not necessarily mark an abrupt passage from the cubic polytype to the hexagonal polytype but can comprise a transition zone exhibiting a certain thickness, which can typically range up to 20 μm. However, in view of the thickness of the second layer, even with such a transition zone, the first interface is sufficiently distant from the second interface.

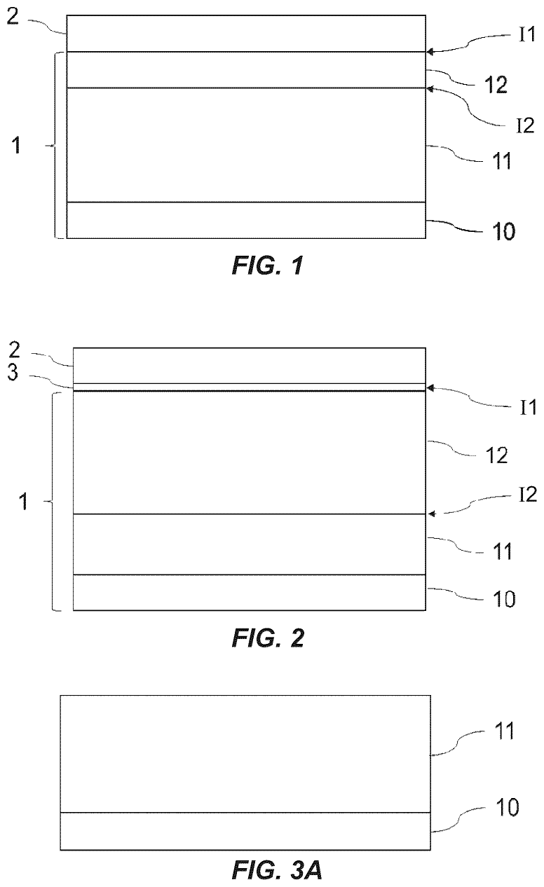

According to a first embodiment, illustrated in FIG. 1, the structure successively comprises, from its back face to its front face, a seed substrate 10, the first layer 11 of polycrystalline SiC mainly of polytype 3C, the second layer 12 of polycrystalline SiC mainly of polytype 4H and/or 6H (the seed substrate and the layers 11 and 12 together forming the support substrate 1) and the active layer 2 of single-crystal SiC of polytype 4H or 6H.

As indicated below, the seed substrate 10 is used for the growth of the first layer 11. It can thus be removed from the structure when its presence is no longer necessary.

In this first embodiment of the structure, the first layer 11 is substantially thicker than the second layer 12. For example, the first layer 11 exhibits a thickness of between 80 and 350 μm, whereas the second layer 12 exhibits a thickness of between 1 and 20 μm.

As the polytype 3C is capable of being obtained at a lower temperature than the polytypes 4H or 6H, the manufacture of this first embodiment of the structure is more economical in energy.

At a subsequent manufacturing step, a back part of the first layer 11 can optionally be removed.

The structure exhibits a first interface Il between the active layer 2, which is single-crystal, and the support substrate 1, which is polycrystalline.

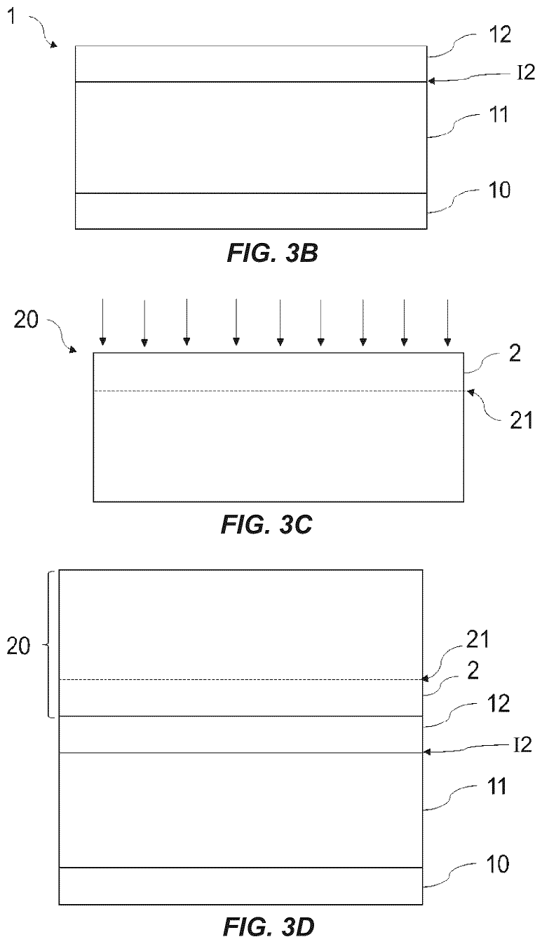

In FIG. 1, the active layer 2 is represented in direct contact with the second layer of polycrystalline SiC 12 but it would also be possible to have a bonding layer (of the type of the layer referenced by reference numeral 3 in FIG. 2) at the interface between these two layers. Such a bonding layer can typically be made of silicon or of tungsten, so as to promote the mechanical strength of the bonding while ensuring electrical conduction between the active layer 2 and the support substrate 1.

Furthermore, the structure exhibits a second interface 12 between the first layer 11, which is mainly of polytype 3C, and the second layer 12, which is mainly of polytype 4H and/or 6H.

The interfaces Il and 12 are thus separated by the thickness of the second layer 12.

According to a second embodiment, illustrated in FIG. 2, the structure successively comprises, from its back face to its front face, a seed substrate 10, the first layer 11 of polycrystalline SiC mainly of polytype 3C, the second layer 12 of polycrystalline SiC mainly of polytype 4H and/or 6H (the seed substrate and the layers 11 and 12 together forming the support substrate 1), a bonding layer 3 and the active layer 2 of single-crystal SiC of polytype 4H or 6H.

As indicated below, the seed substrate 10 is used for the growth of the first layer 11. It can thus be withdrawn from the structure when its presence is no longer necessary.

In this second embodiment of the structure, the first layer 11 is substantially thinner than the second layer 12. For example, the first layer 11 exhibits a thickness of between 80 and 200 μm, whereas the second layer 12 exhibits a thickness of between 150 and 270 μm. The fact that the layer of cubic structure is thinner makes it possible to limit the deformations due to the difference in thermal expansion coefficient between the 3C and 4H/6H structures.

The structure exhibits a first interface I1 between the active layer 2, which is single-crystal, and the support substrate 1, which is polycrystalline.

In FIG. 2, a bonding layer 3 is represented between the active layer 2 and the second layer of polycrystalline SiC 12 but this bonding layer is optional and it would also be possible to carry out a direct bonding between the layers 2 and 12. The bonding layer 3 can typically be made of silicon or of tungsten, so as to promote the mechanical strength of the bonding while ensuring electrical conduction between the active layer 2 and the support substrate 1.

Furthermore, the structure exhibits a second interface I2 between the first layer 11, which is mainly of polytype 3C, and the second layer 12, which is mainly of polytype 4H and/or 6H.

The interfaces I1 and I2 are thus separated by the thickness of the second layer 12.

Optionally, at a subsequent step of the manufacturing process, the first layer 11 can be removed, in which case the second interface is no longer present in the final structure. However, the structure still benefits from the first interface Il between two layers of hexagonal structure that, as explained above, is favorable both as a result of a reduced difference in thermal expansion coefficients and of more similarity of the band structures.

Various processes for the manufacture of these structures will now be described.

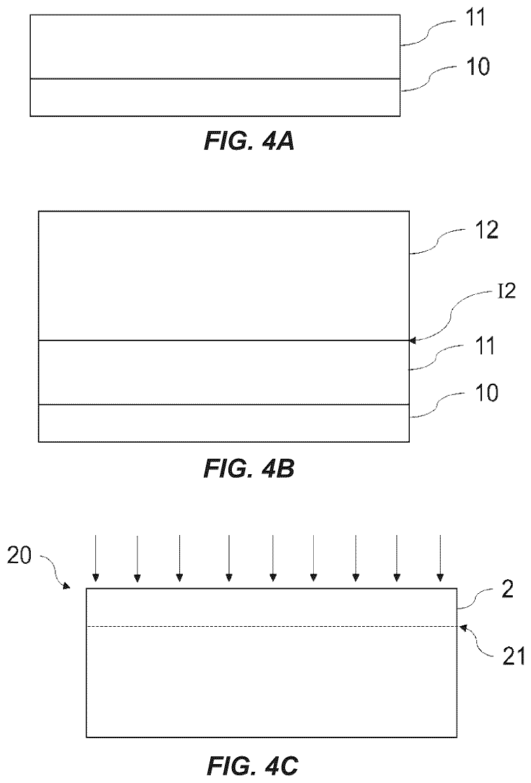

FIGS. 3A to 3D diagrammatically illustrate the stages of a process for the manufacture of the structure of FIG. 1.

With reference to FIG. 3A, the first layer 11 of polycrystalline SiC mainly of polytype 3C is formed on the seed substrate 10. The seed substrate 10 is typically a graphite substrate but any other material, the thermal expansion coefficient of which is close to that of polycrystalline SiC and which preferably exhibits a low cost and/or is reusable, can be employed. Alternative materials to graphite are thus single-crystal SiC and sintered polycrystalline SiC (non-limiting list).

The first layer 11 can be formed by chemical vapor deposition (CVD). This deposition can involve the following precursors (non-limiting examples):
for carbon: ethane, propane or acetylene;
for silicon: silane, tetrachlorosilane, trichlorosilane or dichlorosilane;
or also tetramethylsilane, as common source of carbon and silicon.

These precursors are carried by a carrier gas, which can be chosen from nitrogen, argon, helium and hydrogen.

A person skilled in the art is in a position to define the deposition parameters, in particular, the temperature, as a function of the precursors used and of the plant used to carry out the deposition.

In order to obtain a cubic structure, a relatively low deposition temperature is used, typically between 1100 and 1500° C., and preferably between 1200 and 1400° C. The first layer 11 is grown over a thickness of between 80 and 350 μm. Growth is generally carried out on both faces of the seed substrate so that a layer of polycrystalline SiC mainly of polytype 3C is also formed on the back face of the seed substrate. As this layer is not intended to be retained in the structure, it has not been represented for the sake of simplicity of the drawings.

With reference to FIG. 3B, the second layer 12 of polycrystalline SiC mainly of polytype 4H and/or 6H is formed on the first layer 11, in order to obtain the support substrate 1. The second layer 12 can also be formed by chemical vapor deposition but, in order to obtain a hexagonal structure, a relatively high deposition temperature is used, typically of between 1500 and 2600° C., preferably of between 1700 and 1900° C. or between 1800 and 2400° C., indeed even between 2000 and 2250° C. The growth temperature depends, in particular, on the deposition technique, on the precursors used and on the other operating conditions and is thus given solely by way of indication, the person skilled in the art being in a position to define a growth process suitable for the polytype desired. The precursors can be chosen from the same list as that presented above for the deposition of the first layer.

Besides the abovementioned chemical vapor deposition, the second layer can be formed by high-temperature chemical vapor deposition (HTCVD), by liquid-phase growth (technique known under the acronym TSSG for “Top Seeded Solution Growth”) or also by physical vapor deposition (PVD or PVT).

Although carrying out the deposition at such a temperature requires a very high energy, the fact that the second layer is formed over a low thickness (of between 1 μm and 20 μm) makes it possible to limit the overall energy consumption and the cost of the process. The deposition of the second layer is advantageously carried out in the same chamber as the first layer, in which the deposition temperature is increased in order to modify the polytype of the SiC deposited.

According to an alternative embodiment, the first layer 11 is formed by a sintering process before being transferred into a deposition chamber in which the second layer 12 is subsequently deposited on the first layer 11 by one of the abovementioned deposition or growth techniques.

The transition between the cubic structure of the first layer and the hexagonal structure of the second layer of polycrystalline SiC may not be clear-cut but exhibit a transition zone comprising a mixture of grains of 3C type and of grains of 4H and/or 6H type, over a thickness that can range up to 20 μm. However, in so far as this transition zone is distant from the bonding interface between the active layer and the support substrate, it is not prejudicial to the performance qualities of the structure.

Preferably, the first and the second layer are doped by introduction of dopants during their growth, according to a known technique. Typically, the dopants can be nitrogen, boron, phosphorus or aluminum, according to the type of doping desired. The concentration of dopants is generally between 10¹⁸ and 10²¹ at/cm³.

With reference to FIG. 3C, a donor substrate 20 is provided in which a weakened zone 21 delimiting the active layer 2 to be transferred is formed by implantation of atomic entities (typically hydrogen and/or helium). The donor substrate 20 is a single-crystal SiC substrate of polytype 4H or 6H, commercially available in a suitable size, typically on the order of 150 to 200 mm in diameter.

With reference to FIG. 3D, the donor substrate 20 is bonded to the support substrate 1. Beforehand, for the purpose of a direct bonding of the two substrates, any surface treatment suitable for ensuring that the surfaces in contact are as smooth as possible, that is to say, in particular, exhibiting a roughness of less than 1 nm RMS, preferably of less than 0.5 nm RMS, and more preferably of less than 0.2 nm RMS, is applied. Furthermore, the surfaces are advantageously rendered hydrophobic.

Subsequently, the donor substrate is detached along the weakened zone 21 so as to transfer the active layer 2 onto the support substrate 1 and to obtain the structure of FIG. 1.

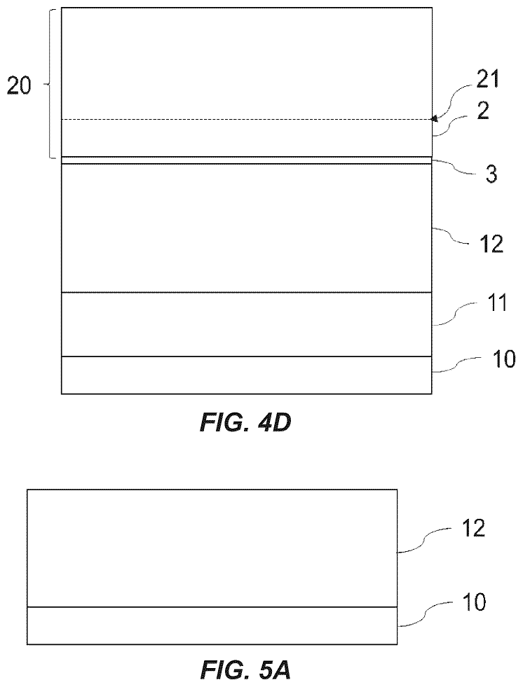

FIGS. 4A to 4D diagrammatically illustrate the stages of a process for the manufacture of the structure of FIG. 2.

With reference to FIG. 4A, the first layer 11 of polycrystalline SiC mainly of polytype 3C is formed on the seed substrate 10. The seed substrate 10 is typically a graphite substrate. The first layer 11 is formed by chemical vapor deposition (CVD). In order to obtain a cubic structure, a relatively low deposition temperature is used, typically between 1100 and 1500° C., preferably between 1200 and 1400° C. The first layer 11 is grown over a thickness of between 1 and 20 μm.

With reference to FIG. 4B, the second layer 12 of polycrystalline SiC mainly of polytype 4H and/or 6H is formed on the first layer 11, in order to obtain the support substrate 1. The second layer 12 is also formed by chemical vapor deposition but, in order to obtain a hexagonal structure, a relatively high deposition temperature is used, typically between 1500 and 2600° C., preferably between 1700 and 1900° C., or between 1800 and 2400° C., indeed even between 2000 and 2250° C. As indicated above, the person skilled in the art is in a position to determine the growing conditions for the desired polytype as a function of the technique employed and of the precursors used. The second layer is formed over a thickness of between 80 and 350 μm. The deposition of the second layer 12 is advantageously carried out in the same chamber as the first layer 11, in which the deposition temperature is increased in order to modify the polytype of the SiC deposited.

As indicated above, the transition between the cubic structure of the first layer 11 and the hexagonal structure of the second layer 12 of polycrystalline SiC may not be clear-cut, and may exhibit a transition zone comprising a mixture of grains of 3C type and of grains of 4H and/or 6H type.

Preferably, the first and the second layer are doped by introduction of dopants during their growth, according to a known technique. Typically, the dopants can be nitrogen, boron, phosphorus or aluminum, according to the type of doping desired. The concentration of dopants is generally between 10¹⁸ and 10²¹ at/cm³.

With reference to FIG. 4C, a donor substrate 20 is provided in which a weakened zone 21 delimiting the active layer 2 to be transferred is formed by implantation of atomic entities (typically hydrogen and/or helium). The donor substrate 20 is a single-crystal SiC substrate of polytype 4H or 6H, commercially available in a suitable size, typically on the order of 150 to 200 mm in diameter.

With reference to FIG. 4D, the donor substrate 20 is bonded to the support substrate 1 via the bonding layer 3. The bonding layer 3 can be deposited beforehand, either on the donor substrate 20 or on the second layer 12 of the support substrate 1. In order to promote good strength of the bonding, a pretreatment of the surfaces to be bonded can be carried out so as to obtain a very low roughness, typically of less than 1 nm RMS, preferably of less than 0.5 nm RMS.

Subsequently, the donor substrate is detached along the weakened zone 21 so as to transfer the active layer 2 onto the support substrate 1 and to obtain the structure of FIG. 2.

In the case where the second layer (polytype 4H and/or 6H) is sufficiently thick, that is to say that it exhibits a thickness of greater than or equal to 100 μm, it is possible to remove the first layer (polytype 3C), in particular, after the formation of an electronic component in the active layer. This withdrawal of the first layer can be carried out by grinding or any other means. It makes it possible to expose, on the back face of the structure, a surface of polytype 4H and/or 6H, on which an electrical contact can subsequently be deposited in the cases where the geometry of the component requires a contact on the back face.

This removal makes it possible to reduce the total electrical resistance of the structure, since one of the contacts is on the back face and since the electric current thus has less material to pass through between the component on the front face and the contact on the back face. Generally, it is frequently planned to modify the thickness of the semiconductor structure by removing a part of the substrate, for example, in order to adapt it to the dimensions of the tools that have to be used or to modify the structure or to adapt the properties of the latter to its specific application.

Thus, a final structure is obtained that is entirely of polytype 4H and/or 6H, and which, thus exhibits a greater uniformity in terms of thermal expansion coefficient and of mechanical properties, but in which the start of the growth of the polycrystalline SiC, which it is planned to remove as mentioned above, and which can sometimes be of poorer crystalline quality as a result of the granular growth of polycrystalline SiC, is carried out at the lower growth temperature of polytype 3C, and is thus more economical in energy.

The processes described above are based on the successive growth, on a seed substrate, of the first layer of polycrystalline SiC mainly of polytype 3C and then of the second layer of polycrystalline SiC mainly of polytype 4H and/or 6H.

Alternatively, it is possible to grow first the second layer of polycrystalline SiC mainly of polytype 4H and/or 6H on a seed substrate and then the first layer of polycrystalline SiC mainly of polytype 3C on the second layer. In order to transfer the single-crystal active layer of 4H or 6H type onto a surface of polytype 4H and/or 6H (which, as indicated above, is more favorable as a result of the similarities of the thermal expansion coefficients and of the band structures), it is then necessary to remove the seed substrate in order to expose the face of the second layer of polycrystalline SiC and to invert the support substrate in order to bond the donor substrate to the second layer.

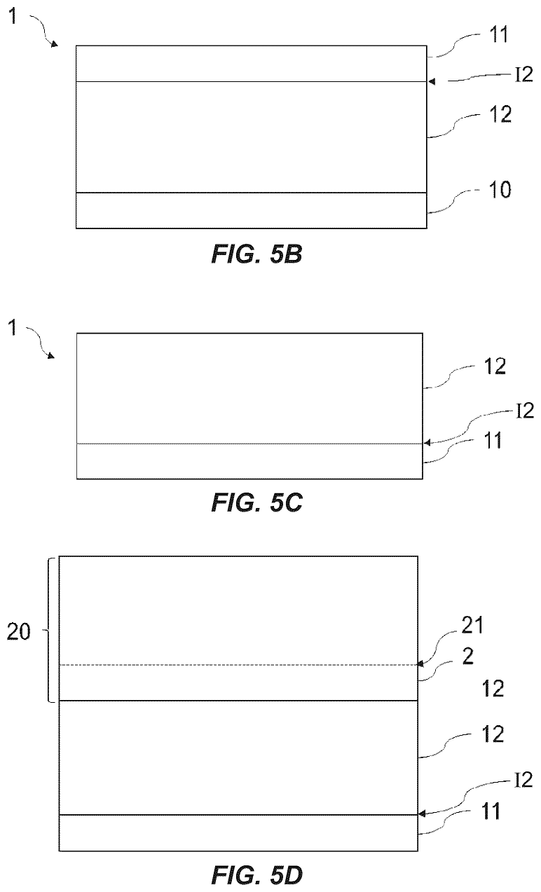

This alternative form is illustrated in FIGS. 5A to 5D. This process can be used to form the semiconductor structure of FIG. 1 or the semiconductor structure of FIG. 2.

With reference to FIG. 5A, the second layer 12 of polycrystalline SiC mainly of polytype 4H and/or 6H is formed on the seed substrate 10. In order to promote the quality of the hexagonal structure of the layer 12, the seed substrate 10 is preferably a substrate of single-crystal or polycrystalline SiC mainly of polytype 4H and/or 6H. The second layer 12 is formed by chemical vapor deposition with a relatively high deposition temperature, typically between 1500 and 2600° C., preferably between 1700 and 1900° C. or between 1800 and 2400° C., indeed even between 2000 and 2250° C. As indicated above, the person skilled in the art is in a position to determine the growing conditions for the desired polytype as a function of the technique employed and of the precursors used.

With reference to FIG. 5B, the first layer 11 of polycrystalline SiC mainly of polytype 3C is formed on the second layer 12. The first layer 11 is formed by chemical vapor deposition at a relatively low deposition temperature, typically between 1100 and 1500° C., preferably between 1200 and 1400° C. The deposition of the first layer is advantageously carried out in the same chamber as that of the second layer, the deposition temperature being lowered in order to promote a change in polytype of the SiC deposited.

Preferably, the first and the second layer are doped by introduction of dopants during their growth, according to a known technique. Typically, the dopants can be nitrogen, boron, phosphorus or aluminum, according to the type of doping desired. The concentration of dopants is generally between 10¹⁸ and 10²¹ at/cm³.

With reference to FIG. 5C, the seed substrate 10 is removed so as to expose the back face of the second layer 12, which is mainly of polytype 4H and/or 6H. The support substrate 1 thus consists solely of the layers 11 and 12.

As in the other embodiments of the process (cf. FIGS. 3C and 4C), a donor substrate 20 is furthermore provided in which a weakened zone 21 delimiting the active layer 2 to be transferred is formed by implantation of atomic entities (typically hydrogen and/or helium). The donor substrate 20 is a single-crystal SiC substrate of polytype 4H or 6H, commercially available in a suitable size, typically on the order of 150 to 200 mm in diameter.

With reference to FIG. 5D, the donor substrate 20 is bonded to the support substrate 1 either directly or via the bonding layer described above. To this end, the support substrate 1 is inverted in order for the second layer 12, which was on the back side during the manufacture of the support substrate 1, to be oriented toward the front in order to receive the donor substrate 20.

Subsequently, the donor substrate is detached along the weakened zone 21 so as to transfer the active layer 2 onto the support substrate 1 and to obtain a semiconductor structure similar to that of FIGS. 1 and 2, in which the support substrate 1 is devoid of the seed substrate 10.

The semiconductor structure obtained can advantageously be used in the manufacture of electronic devices for power applications and/or radiofrequency applications.

To this end, it is possible to form by epitaxial regrowth on the active layer one or more additional semiconductor layers intended for the formation of electronic components.

For example, the electronic components formed in or on the active layer can comprise: one or more transistors, one or more diodes, one or more power components or one or more radiofrequency components (non-limiting list). A radiofrequency component typically comprises a line for transmission of a radiofrequency electric signal and optionally one or more transistors. A power component is defined as being a component suitable for transporting an electric current exhibiting a power of 50 W or more.

1. A method of manufacturing a semiconductor structure including a support substrate of polycrystalline silicon carbide and an active layer of single-crystal silicon carbide, the method comprising:
forming a support substrate including a stack of a first layer of polycrystalline SiC mainly of polytype 3C and of a second layer of polycrystalline SiC mainly of polytype 4H and/or 6H,
bonding a donor substrate including an active layer of single-crystal SiC of polytype 4H or 6H to a face of polytype 4H and/or 6H of the support substrate, and
transferring the active layer onto the support substrate.

2. The method of claim 1, wherein the forming of the support substrate comprises growing the first layer on a seed substrate and then growing the second layer on the first layer.

3. The method of claim 1, wherein the forming of the support substrate successively comprises growing the second layer on a seed substrate, growing the first layer on the second layer, and removing the seed substrate to expose a face of the second layer for the bonding of the donor substrate.

4. The method of claim 3, wherein the seed substrate is a single-crystal or polycrystalline SiC substrate mainly of polytype 4H and/or 6H.

5. The method of claim 2, further comprising growing the first layer to a thickness of between 1 and 20 μm and growing the second layer to a thickness of between 80 and 350 μm.

6. The method of claim 2, further comprising growing the first layer to a thickness of between 80 and 200 μm and growing the second layer to a thickness of between 150 and 270 μm.

7. The method of claim 2, further comprising growing the first layer and the second layer by chemical vapor deposition.

8. The method of claim 2, further comprising growing the first layer at a temperature between 1100 and 1500° C.

9. The method of claim 2, further comprising growing the second layer at a temperature of between 1500 and 2600° C.

10. The method of claim 2, further comprising introducing dopants during the growth of the first layer and of the second layer.

11. The method of claim 1, in which wherein the bonding of the donor substrate to the face of polytype 4H and/or 6H of the support substrate comprises bonding the donor substrate directly to the face of polytype 4H and/or 6H of the support substrate.

12. The method of claim 1, wherein the bonding of the donor substrate to the face of polytype 4H and/or 6H of the support substrate comprises bonding the donor substrate to the face of polytype 4H and/or 6H of the support substrate via a bonding layer.

13. The method of claim 12, further comprising forming the bonding layer to comprise silicon or tungsten.

14. The method of claim 1, further comprising, before the bonding, implanting atomic entities in the donor substrate to form a weakened zone delimiting the active layer and, after the bonding, detaching the donor substrate along the weakened zone to transfer the active layer onto the support substrate.

15. The method of claim 1, further comprising growing the first layer to a thickness of between 1 and 20 μm and then growing the second layer to a thickness of between 80 and 350 μm, and after the transferring of the active layer onto the support substrate, removing the first layer.

16. A semiconductor structure successively comprising, from back face of the structure to its a front face of the structure:
a first layer of polycrystalline SiC mainly of polytype 3C;
a second layer of polycrystalline SiC mainly of polytype 4H and/or 6H; and
an active layer of single-crystal SiC of polytype 4H or 6H.

17. The semiconductor structure of claim 16, wherein:
the first layer has a thickness between 80 and 350 μm; and
the second layer has a thickness between 1 and 20 μm.

18. The semiconductor structure of claim 16, wherein:
the first layer has a thickness between 80 and 200 μm; and
the second layer has a thickness between 150 and 270 μm.

19. An electronic device, comprising:
a semiconductor structure according to claim 16; and
at least one electronic component in or on the active layer.

20. The electronic device of claim 19, wherein the at least one electronic component comprises a transistor, a diode, an electronic power component, and/or an electronic radiofrequency component.
